(19) United States
(12) Patent Application Publication
(10) Pub. No.: US 2024/0171133 A1
(43) Pub. Date: May 23, 2024

(54) SENSOR DRIVER PROVIDING HIGH POWER SUPPLY REJECTION RATIO

(71) Applicant: INVENSENSE, INC., San Jose, CA (US)

(72) Inventors: Athanasios Sarafianos, Landen (BE); Tim Piessens, Bornem (BE)

(21) Appl. No.: 18/461,050

(22) Filed: Sep. 5, 2023

Related U.S. Application Data
(60) Provisional application No. 63/426,920, filed on Nov. 21, 2022.

(51) Int. Cl. H03F 3/00; H03F 1/30; H03F 3/45

(52) U.S. Cl. CPC H03F 3/005; H03F 1/303; H03F 3/45475; H03F 2200/261

(57) ABSTRACT

A sensor driver providing high power supply rejection ratio is provided herein. A circuit can include a charge pump that comprises an input terminal and an output terminal, wherein the input terminal is operatively connected to a voltage supply. The charge pump further comprises circuitry that decouples an input voltage from the voltage supply from an output voltage of the charge pump and mixes defined frequency disturbances back to baseband. The circuit also includes an error amplifier configured to provide high power supply rejection ratio at baseband, wherein the output terminal of the charge pump is operatively connected to an input node of the error amplifier. Further, the circuit includes a capacitive micro-electromechanical system sensor operatively connected to an output node of the error amplifier.

### CROSS REFERENCE TO RELATED APPLICATIONS

This application claims the benefit of priority to U.S. Provisional Application Number 63/426,920; filed Nov. 21, 2022, and entitled “SENSOR DRIVER PROVIDING HIGH PSRR,” the entirety of which is expressly incorporated herein by reference.

### TECHNICAL FIELD

This disclosure relates generally to the field of capacitive micro-electromechanical system sensor drivers, and more specifically, to capacitive micro-electromechanical system sensor drivers having a high power supply rejection ratio.

### BACKGROUND

Traditional sensor drivers can suffer from power supply rejection weaknesses at discrete frequencies. This is due to intermixing of the supply ripple with the drive frequency. This can lead to errors of more than, for example, 4000 times the noise floor or, in another example, 4000 times the least significant bit (LSB). Accordingly, unique challenges exist to provide sensor drivers that do not suffer from power supply rejection weaknesses at discrete frequencies.

### SUMMARY

The subject application relates to sensor drivers that provide high power supply rejection ratios. Provided herein is a device that includes a charge pump and an error amplifier. The charge pump increases a first value of an input voltage by a defined amount, resulting in an output voltage that comprises a second value. The charge pump includes circuitry that decouples the input voltage of the charge pump from the output voltage of the charge pump and in the process mixes defined frequency disturbances back to baseband. The error amplifier is configured to drive a micro-electromechanical system (MEMs) capacitive sensor. The error amplifier receives the output voltage from the charge pump and removes defined mixed down frequency disturbances. An output of the error amplifier is provided as input to the micro-electromechanical system capacitive sensor.

The circuitry can include a first number of flying capacitors and a second number of Direct Current (DC) capacitors that are arranged in a defined configuration. The defined configuration can decouple the input voltage and the output voltage during distinct phases of the charge pump. The first number of flying capacitors can include no fixed connection to ground, and the second number of DC capacitors can include a fixed connection to ground. Further, the distinct phases comprise a first phase and a second phase, wherein the first phase is a sampling phase and the second phase is a gain phase.

When the charge pump is configured in a one to two (1:2) voltage conversion ratio, during a first phase of the distinct phases. the first number of flying capacitors and the second number of DC capacitors are arranged in a parallel configuration connected to the input. Further, during a second phase of the distinct phases, the first number of flying capacitors are configured in a parallel arrangement and the second number of DC capacitors are connected in series with the parallel arrangement towards the output.

When the charge pump is configured in a two to three (2:3) voltage conversion ratio, during a first phase of the distinct phases, a series configuration comprising the first number of flying capacitors are placed in a parallel configuration with the second number of DC capacitors. Further, during a second phase of the distinct phases, the first number of flying capacitors are configured in a parallel arrangement and the second number of DC capacitors are connected in series with the parallel arrangement.

The charge pump can be automatically configured based on the input voltage to accommodate a continuous supply range from around 1.62 volts to about 3.6 volts. Further, the defined amount is equal to a value of the input voltage. A ratio of an output voltage value to an input voltage value is a function of a topology of the charge pump. The charge pump is configured to mix noise at a drive frequency towards direct current (DC), and wherein the error amplifier removes noise at DC. In an example, the charge pump is a gearbox charge pump and the error amplifier is a sensor drive linear voltage regulator. Further, the device is configured to facilitate an improvement to a signal to noise ratio as compared to a conventional signal to noise ratio amount.

Another embodiment relates to a circuit that includes a charge pump that comprises an input terminal and an output terminal, wherein the input terminal is operatively connected to a voltage supply. The charge pump further comprises circuitry that decouples an input voltage from the voltage supply from an output voltage of the charge pump and mixes defined frequency disturbances back to baseband. The circuit also includes an error amplifier configured to provide high power supply rejection ratio at baseband, wherein the output terminal of the charge pump is operatively connected to an input node of the error amplifier. Further, the circuit includes a capacitive micro-electromechanical system sensor operatively connected to an output node of the error amplifier.

The circuitry of the charge pump can include a first number of flying capacitors and a second number of Direct Current (DC) capacitors that are arranged in a defined configuration. The defined configuration decouples the input voltage and the output voltage during distinct phases of the charge pump.

Based on the charge pump being configured in a one to two (1:2) voltage conversion ratio, during a first phase of the distinct phases, the first number of flying capacitors and the second number of DC capacitors are arranged in a parallel configuration connected to the input terminal. Additionally, during a second phase of the distinct phases, the first number of flying capacitors are configured in a parallel arrangement and the second number of DC capacitors are connected in series with the parallel arrangement towards the output node.

Based on the charge pump being configured in a two to three (2:3) voltage conversion ratio, during a first phase of the distinct phases, a series configuration comprising the first number of flying capacitors are placed in a parallel configuration with the second number of DC capacitors. Further, during a second phase of the distinct phases, the first number of flying capacitors are configured in a parallel arrangement and the second number of DC capacitors are connected in series with the parallel arrangement.

In an example, the first number of flying capacitors comprise no fixed connection to ground, and the second number of DC capacitors comprises a fixed connection to ground. The charge pump can be configured to accommodate a continuous supply range from around 1.62 volts to about 3.6 volts. Further. the charge pump is configured to mix noise at a drive frequency towards a direct current (DC), and wherein the error amplifier removes supply ripple at DC.

### BRIEF DESCRIPTION OF THE DRAWINGS

Various non-limiting embodiments are further described with reference to the accompanying drawings in which:

FIG. 1 illustrates an example of a traditional system utilized to drive a sensor.

FIG. 2 illustrates an example, non-limiting, plot of a power supply rejection baseline using a conventional drive for a capacitive MEMS pressure sensor.

FIG. 3 illustrates an example, non-limiting, device that provides a high power supply rejection ratio (PSRR) in accordance with one or more embodiments described herein.

FIG. 4 illustrates example, non-limiting, circuits for a first configuration of a charge pump in accordance with one or more embodiments described herein.

FIG. 5 illustrates example, non-limiting, circuits for a second configuration of a charge pump in accordance with one or more embodiments described herein.

FIG. 6 illustrates example, non-limiting, circuits for a third configuration of a charge pump in accordance with one or more embodiments described herein.

FIG. 7 illustrates a flow diagram of an example, non-limiting, method for employing a sensor driver that provides a high power supply rejection ratio in accordance with one or more embodiments described herein.

### DETAILED DESCRIPTION

One or more embodiments are now described more fully hereinafter with reference to the accompanying drawings in which example embodiments are shown. In the following description, for purposes of explanation, numerous specific details are set forth in order to provide a thorough understanding of the various embodiments.

The disclosed embodiments provide a circuit, system, device, and related method that provides high PSRR in a capacitive sensor readout. For example, the disclosed embodiments cascade a gearbox charge pump with a sensor drive low drop out (LDO). The gear box charge pump does not have a direct connection between in and out in any of the phases.

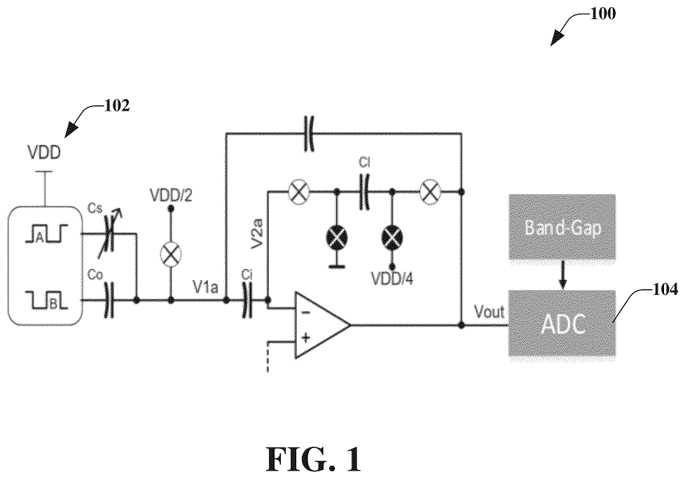

For example, FIG. 1 illustrates an example of a traditional system 100 utilized to drive a sensor. For example, the sensor can be a MEMS sensor, a pressure sensor, or another type of capacitive sensor. The traditional system 100 drives the sensor with a square wave that is directly fed from the supply 102. The supply is then taken as the reference for the ADC 104, canceling out the errors on the supply 102. This can have a serious impact on the power supply rejection ratio (PSRR) of the traditional system 100. For example, a problem with the approach of the traditional system 100 of FIG. 1 is that harmonics are created. These harmonics can fall back to DC when there is a supply voltage disturbance/ripple present.

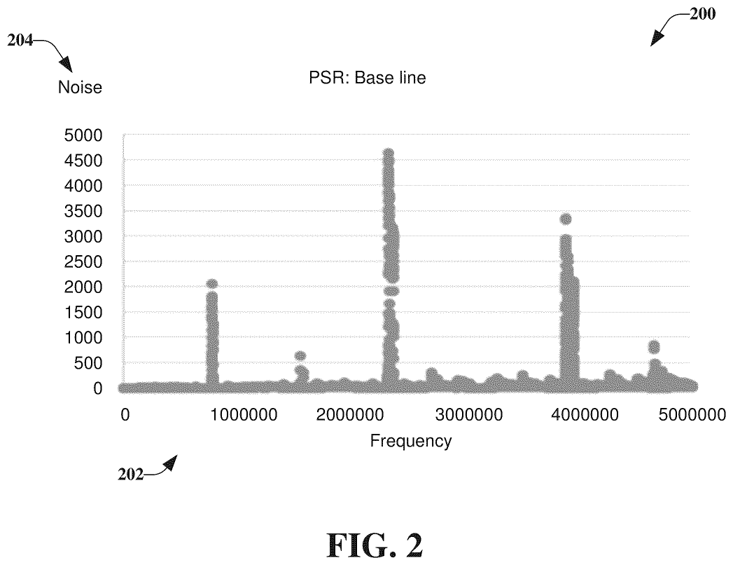

FIG. 2 illustrates an example, non-limiting, plot 200 of a Power Supply Rejection (PSR) baseline using a conventional drive for a capacitive MEMS pressure sensor. Frequency 202 is represented on the horizonal axis and noise 204 is represented on the vertical axis. As shown in the plot 200 every supply ripple at the same frequency as the internal clock will generate a huge noise tone, which is undesirable.

Further, as mentioned, the traditional approach suffers from power supply rejection weaknesses at discrete frequencies due to intermixing of the supply ripple with the drive frequency. As shown in the plot 200, this can lead to errors of more than about 4000 pascal (Pa) according to the example from a pressure sensor.

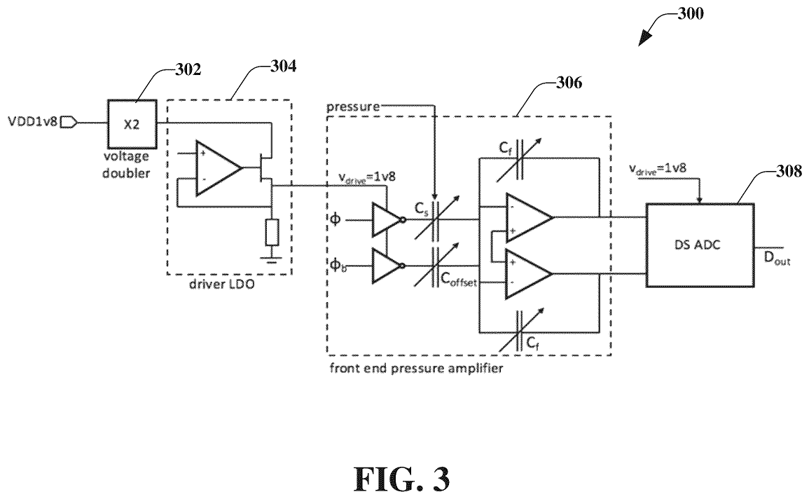

To overcome the above and related ends, the disclosed embodiments utilize a two-stage approach as will be discussed with respect to FIG. 3, which illustrates an example, non-limiting, device 300 that provides a high power supply rejection ratio (PSRR) in accordance with one or more embodiments described herein. With utilization of the disclosed embodiments, the error (depicted for the traditional approach with respect to FIG. 2) can be reduced to less than 4 pascal (Pa).

The device 300 includes a charge pump 302, illustrated as a voltage doubler and an error amplifier 304 that can drive a MEMs capacitor, which is illustrated in FIG. 3 as a driver LDO. The device 300 also includes a front end pressure amplifier circuit 306 and a DS ADC 308. The device 300 includes various properties including, for example, that the charge pump can mix noise at the drive frequency towards DC and the driver LDO removes all (or as much as possible) noise at DC. In this way, the total sensor driver removes all (or as many as possible) PSRR issues, which are inherent to the traditional approach, as discussed above.

In further detail, during a first stage of the two-stage approach, the voltage doubler (e.g., the charge pump 302) increases the supply voltage to a value that is higher than the supply voltage value. Thus, the voltage doubler can be used as not only a supply but also as a sample and hold stage. During a second stage of the two-stage approach, the driver LDO (c.g., the error amplifier 304) can fold all high frequency disturbances back to baseband and in this baseband frequency range there can be a very high suppression of the LDO driver.

In a traditional charge pump, there is always a phase where the input and the output are connected through a capacitor. The problem with this is that at high frequencies these capacitors are short-circuits (e.g., have a low impedance). This results in a short circuit between the input and the output and the supply noise is no longer mixed to baseband, which is a problem associated with traditional designs.

As mentioned above, the disclosed embodiments relate to implementation of a charge pump such that there are two distinct phases. In each phase, the input voltage and the output voltage are always decoupled. A benefit of using a charge pump in this setup is that multiple conversion ratios can be easily implemented with the charge pump so that the supply range over which operation can occur can be extended. Further, a drive supply, which is normally higher than the VDD supply can be applied. This improves SNR. Accordingly, improved noise metrics can be achieved.

According to the disclosed embodiments, the drive voltage can be made independent of the supply voltage and can be even higher than the actual supply. An advantage of this is that the SNR improves proportional to the drive voltage. Another advantage is that a continuous supply range from around 1.62 V to about 4.2 V can be accommodated by a gear box charge pump. It is also noted that the disclosed embodiments have a charge pump that does not have a flying cap that connects VDD with VOUT in one phase. This comes at the cost of extra area, but it provides the high PSRR needed.

The device 300 is configured to facilitate an improvement to a signal to noise ratio as compared to a conventional signal to noise ratio. In further detail, the charge pump 302 increases a first value of an input voltage by a defined amount, resulting in an output voltage that comprises a second value. The charge pump 302 includes circuitry that decouples the input voltage of the charge pump from the output voltage of the charge pump and in the process mixes defined frequency disturbances back to baseband.

In an example, the charge pump 302 is automatically configured based on the input voltage to accommodate a continuous supply range from around 1.62 volts to about 3.6 volts. The defined amount is equal to a value of the input voltage. A ratio of an output voltage value to an input voltage value is a function of a topology of the charge pump. According to some implementations, the charge pump 302 is configured to mix noise at a drive frequency towards direct current (DC), and the error amplifier removes noise at DC. In an example. the charge pump is a gearbox charge pump and the error amplifier is a sensor drive linear voltage regulator.

The circuitry includes a first number of flying capacitors and a second number of Direct Current (DC) capacitors. The flying capacitors and the DC capacitors are arranged in a defined configuration. The defined configuration decouples the input voltage and the output voltage during distinct phases of the charge pump. The flying capacitors comprise no fixed connection to ground, and the DC capacitors comprise a fixed connection to ground. Further, the distinct phases comprise a first phase and a second phase, wherein the first phase is a sampling phase and the second phase is a gain phase.

The error amplifier 304 is configured to drive a micro-electromechanical system capacitive sensor. The error amplifier 304 receives the output voltage from the charge pump 302 and removes defined mixed down frequency disturbances. An output of the error amplifier 304 is provided as input to the micro-electromechanical system capacitive sensor.

In an implementation, the charge pump is configured in a one to two (1:2) voltage conversion ratio. Thus, during a first phase of the distinct phases, the first number of flying capacitors and the second number of DC capacitors are arranged in a parallel configuration connected to the input. During a second phase of the distinct phases, the first number of flying capacitors are configured in a parallel arrangement and the second number of DC capacitors are connected in series with the parallel arrangement towards the output.

According to another implementation, the charge pump is configured in a two to three (2:3) voltage conversion ratio. Thus, during a first phase of the distinct phases, a series configuration comprising the first number of flying capacitors are placed in a parallel configuration with the second number of DC capacitors. During a second phase of the distinct phases. the first number of flying capacitors are configured in a parallel arrangement and the second number of DC capacitors are connected in series with the parallel arrangement.

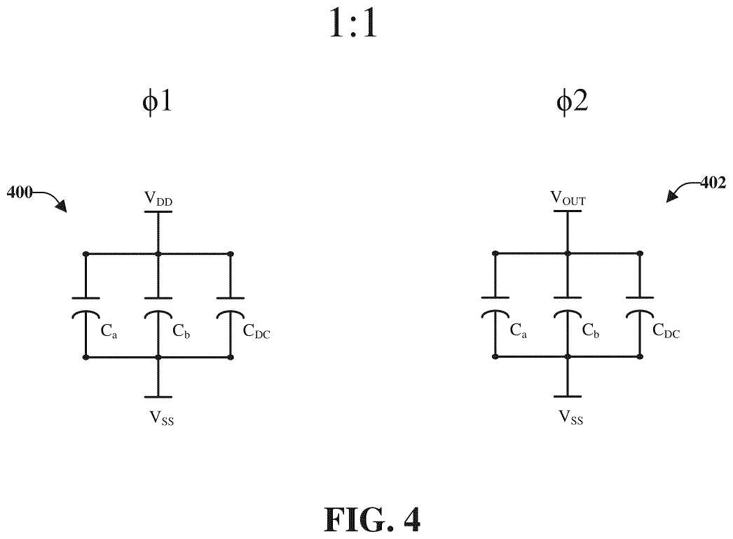

FIG. 4 illustrates example, non-limiting, circuits for a first configuration of a charge pump in accordance with one or more embodiments described herein. A first circuit 400 of FIG. 4 is configured for a first phase (ϕ1); and a second circuit 402 of FIG. 4 is configured for a second phase (ϕ2). The first circuit 400 and the second circuit 402 represent a one to one (1:1) voltage conversion ratio, which is a regular case of a track and hold sampling stage.

The first circuit 400 includes a multitude of capacitors, illustrated as a first capacitor Cₐ, a second capacitor C_{b}, and a third capacitor C_{DC}. The capacitors Cₐ, C_{b}, and C_{CDC} are connected between a supply voltage V_{DD} and ground (e.g., V_{SS}). For the first circuit 400 (e.g., the first phase), the capacitors Cₐ, C_{b}, and C_{CDC} are charged to a value of the input supply voltage V_{DD}. For the second circuit 402 (e.g., the second phase), the capacitors Cₐ, C_{b}, and C_{CDC} are connected to the output voltage V_{OUT}. For the first phase, the first circuit 400 is tracked to the input. For the second phase, in the second circuit 402, the input is disconnected and the circuit is only connected to the output.

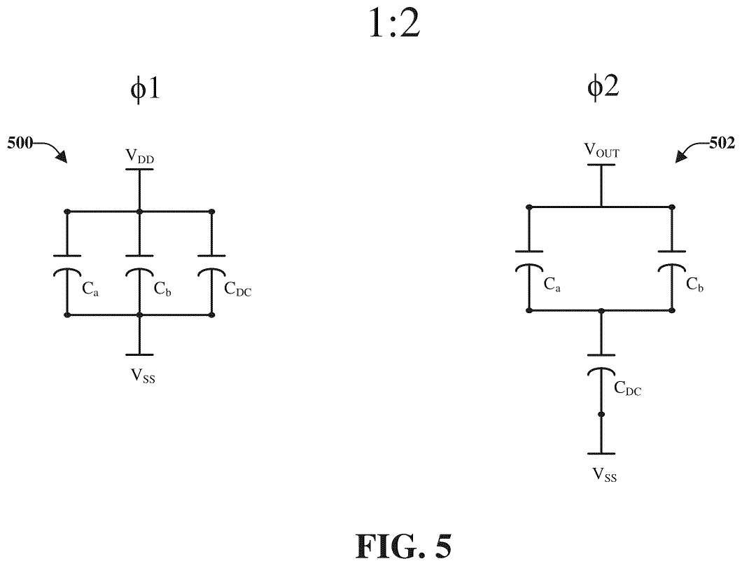

FIG. 5 illustrates example, non-limiting, circuits for a second configuration of a charge pump in accordance with one or more embodiments described herein. A first circuit 500 of FIG. 5 is configured for a first phase (ϕ1); and a second circuit 502 of FIG. 5 is configured for a second phase (ϕ2). The first circuit 500 and the second circuit 502 represent a one to two (1:2) voltage conversion ratio.

The first circuit 500 includes a multitude of capacitors, illustrated as a first capacitor Cₐ, a second capacitor C_{b}, and a third capacitor C_{DC}. In the first phase (the first circuit 500), a capacitor is charged between the input supply V_{DD} and ground (e.g., V_{SS}). In the next phase (the second circuit 502), the connection might be between the output V_{OUT} and the input supply V_{DD}. However, this provides a low-impedance path between input and output for high-frequency disturbances/supply ripple.

Accordingly, as illustrated in FIG. 5, the first circuit 500 is configured such that the third capacitor C_{DC} is added. The third capacitor C_{DC} is used in parallel with the other capacitors (e.g., the first capacitor Cₐ, the second capacitor C_{b}) in the first phase. The first capacitor Cₐ, the second capacitor C_{b}, and the third capacitor C_{DC} are charged to the value of the input supply V_{DD}.

In the next phase or second phase (e.g., the second circuit 502) the capacitors are stacked on top of each other. In this configuration, the first capacitor Cₐ and the second capacitor C_{b} are in a parallel arrangement. Further, the third capacitor C_{DC} is arranged in a series configuration with the first capacitor Cₐ and the second capacitor C_{b}. In the configuration of the second circuit 502, the value of the output voltage Vour is equal to two times the value of the input supply V_{DD}. In addition, the input is decoupled from the output in the configuration of the second circuit 502.

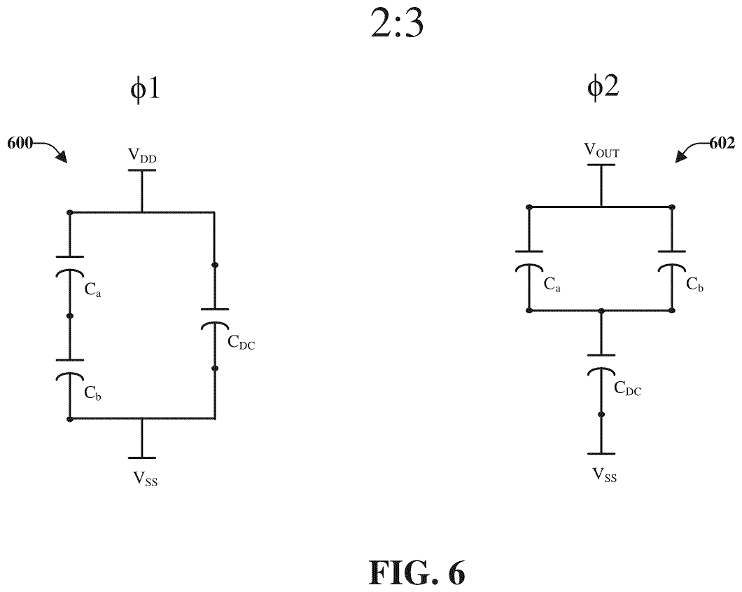

FIG. 6 illustrates example, non-limiting, circuits for a third configuration of a charge pump in accordance with one or more embodiments described herein. A first circuit 600 of FIG. 6 is configured for a first phase (ϕ1); and a second circuit 602 of FIG. 6 is configured for a second phase (ϕ2). The first circuit 600 and the second circuit 602 represent a two to three (2:3) voltage conversion ratio.

The first circuit 600 includes a multitude of capacitors, illustrated as a first capacitor Cₐ, a second capacitor C_{b}, and a third capacitor C_{DC}. In the first phase (the first circuit 600), the first capacitor Cₐ and the second capacitor C_{b} are in a series configuration with one another. Further, the third capacitor C_{DC} is in a parallel configuration with the series configuration of the first capacitor Cₐ and the second capacitor C_{b}. During the first phase (the first circuit 600), the third capacitor C_{DC} is used to store the input supply voltage V_{DD}.

The second circuit 602 is configured such that the first capacitor Cₐ and the second capacitor C_{b} are in a parallel configuration with one another. Further, the third capacitor C_{DC} is in a series configuration with the parallel configuration of the first capacitor Cₐ and the second capacitor C_{b}. Accordingly, the first phase is a sampling and hold phase and the second phase is a gain phase. In the example of FIG. 6, the sampling in phase one is performed at a gain of one (1), and the output after phase two is a gain of two (2). It is noted that the disclosed embodiments can be extended to any voltage conversion ratio and the examples with respect to FIGS. 4, 5, and 6 are for explanation purposes only.

In further detail, a charge pump (e.g., the charge pump 302, the circuits of FIG. 4. the circuits of FIG. 5, the circuits of FIG. 6) comprises an input terminal and an output terminal. The input terminal is operatively connected to a voltage supply. The charge pump further comprises circuitry that decouples an input voltage from the voltage supply from an output voltage of the charge pump and mixes defined frequency disturbances back to baseband.

Further, an error amplifier (e.g., the error amplifier 304) is configured to provide high PSRR at baseband. The output terminal of the charge pump is operatively connected to an input node of the error amplifier. The circuit can also include a capacitive micro-electromechanical system sensor operatively connected to an output node of the error amplifier.

The circuitry of the charge pump can include a first number of flying capacitors and a second number of Direct Current (DC) capacitors that are arranged in a defined configuration. The defined configuration decouples the input voltage and the output voltage during distinct phases of the charge pump. Additionally, the charge pump is configured to mix noise at a drive frequency towards a direct current (DC), and the error amplifier removes supply ripple at baseband.

Methods that can be implemented in accordance with the disclosed subject matter, will be better appreciated with reference to various flow charts. While, for purposes of simplicity of explanation, the methods are shown and described as a series of blocks, it is to be understood and appreciated that the disclosed aspects are not limited by the number or order of blocks, as some blocks can occur in different orders and/or at substantially the same time with other blocks from what is depicted and described herein. Moreover, not all illustrated blocks can be required to implement the disclosed methods. It is to be appreciated that the functionality associated with the blocks can be implemented by software, hardware, a combination thereof, or any other suitable means (e.g., device, system, process, component, and so forth). Additionally, it should be further appreciated that the disclosed methods are capable of being stored on an article of manufacture to facilitate transporting and transferring such methods to various devices. Those skilled in the art will understand and appreciate that the methods could alternatively be represented as a series of interrelated states or events, such as in a state diagram.

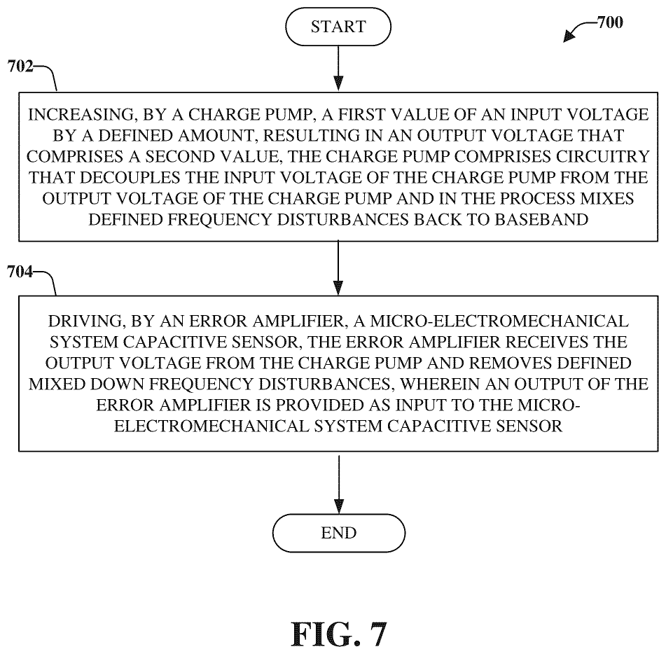

FIG. 7 illustrates a flow diagram of an example, non-limiting, method 700 for employing a sensor driver that provides a high power supply rejection ratio in accordance with one or more embodiments described herein. The method 700 can be implemented by a device (e.g., the device 300 of FIG. 3), a circuit (e.g., the circuits of FIG. 4, the circuits of FIG. 5. the circuits of FIG. 6), a sensor driver, a MEMS sensor, a MEMS microphone, a system including a processor, and so on.

As mentioned, traditionally, when a supply voltage is used, weaknesses of multiples of the sampling frequency are introduced, which can lead to very high errors in measured physical quantity. With utilization of the disclosed embodiments, errors that are orders of magnitude lower can be achieved. For example, a test case has achieved a reduction of errors to a value of less than 4 pascal, which is an improvement of 3 orders of magnitude.

The method 700 starts, at 702, when a first value of an input voltage is increased, by a charge pump, by a defined amount, resulting in an output voltage that comprises a second value. The charge pump comprises circuitry that decouples the input voltage of the charge pump from the output voltage of the charge pump. Further, during the process of increasing the first value, the charge pump mixes defined frequency disturbances back to baseband.

At 704, the method drives, by an error amplifier, a micro-electromechanical system capacitive sensor. For example, the error amplifier receives the output voltage from the charge pump and removes defined mixed down frequency disturbances. An output of the error amplifier is provided as input to the micro-electromechanical system capacitive sensor.

According to some implementations, the charge pump can be automatically configured based on the input voltage to accommodate a continuous supply range from around 1.62 volts to about 3.6 volts. In some implementations, the defined amount is equal to a value of the input voltage. A ratio of an output voltage value to an input voltage value is a function of a topology of the charge pump.

In an example, the charge pump is configured to mix noise at a drive frequency towards direct current (DC), and the error amplifier removes noise at DC. In some cases, the charge pump is a gearbox charge pump and the error amplifier is a sensor drive linear voltage regulator. Additionally, the method can be configured to facilitate an improvement to a signal to noise ratio as compared to a conventional signal to noise ratio.

In an example, the circuitry comprises a first number of flying capacitors and a second number of Direct Current (DC) capacitors that are arranged in a defined configuration. The defined configuration is configured to decouple the input voltage and the output voltage during distinct phases of the charge pump. The first number of flying capacitors can include no fixed connection to ground and the second number of DC capacitors can include a fixed connection to ground. Additionally, the distinct phases can include a first phase and a second phase. The first phase can be a sampling phase and the second phase can be a gain phase.

According to an implementation, the charge pump is configured in a one to two (1:2) voltage conversion ratio. Further to this implementation, during a first phase of the distinct phases, the first number of flying capacitors and the second number of DC capacitors are arranged in a parallel configuration connected to the input. During a second phase of the distinct phases, the first number of flying capacitors are configured in a parallel arrangement and the second number of DC capacitors are connected in series with the parallel arrangement towards the output.

In accordance with another implementation, the charge pump is configured in a two to three (2:3) voltage conversion ratio. Further to this implementation, during a first phase of the distinct phases, a series configuration comprising the first number of flying capacitors are placed in a parallel configuration with the second number of DC capacitors. During a second phase of the distinct phases, the first number of flying capacitors are configured in a parallel arrangement and the second number of DC capacitors are connected in series with the parallel arrangement.

Reference throughout this specification to “one embodiment,” or “an embodiment,” means that a particular feature, structure, or characteristic described in connection with the embodiment is included in at least one embodiment. Thus, the appearances of the phrase “in one embodiment,” “in one aspect,” or “in an embodiment,” in various places throughout this specification are not necessarily all referring to the same embodiment. Furthermore, the particular features, structures, or characteristics can be combined in any suitable manner in one or more embodiments.

In addition, the words “example” and “exemplary” are used herein to mean serving as an instance or illustration. Any embodiment or design described herein as “example” or “exemplary” is not necessarily to be construed as preferred or advantageous over other embodiments or designs. Rather, use of the word example or exemplary is intended to present concepts in a concrete fashion. As used in this application, the term “or” is intended to mean an inclusive “or” rather than an exclusive “or.” That is, unless specified otherwise or clear from context, “X employs A or B” is intended to mean any of the natural inclusive permutations. That is, if X employs A; X employs B; or X employs both A and B. then “X employs A or B” is satisfied under any of the foregoing instances. In addition, the articles “a” and “an” as used in this application and the appended claims should generally be construed to mean “one or more” unless specified otherwise or clear from context to be directed to a singular form.

In addition, the various embodiments can be implemented as a method, apparatus, or article of manufacture using standard programming and/or engineering techniques to produce software, firmware, hardware, or any combination thereof to control a computer to implement the disclosed subject matter. The term “article of manufacture” as used herein is intended to encompass a computer program accessible from any computer-readable device, machine-readable device, computer-readable carrier, computer-readable media, machine-readable media, computer-readable (or machine-readable) storage/communication media. For example, computer-readable media can comprise, but are not limited to, a magnetic storage device, e.g., hard disk; floppy disk; magnetic strip(s); an optical disk (e.g., compact disk (CD), a digital video disc (DVD), a Blu-ray Disc™ (BD)); a smart card; a flash memory device (c.g., card, stick, key drive); and/or a virtual device that emulates a storage device and/or any of the above computer-readable media. Of course, those skilled in the art will recognize many modifications can be made to this configuration without departing from the scope or spirit of the various embodiments.

The above description of illustrated embodiments of the subject disclosure, including what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the subject matter has been described herein in connection with various embodiments and corresponding figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

What is claimed is:

1. A device, comprising:
a charge pump that increases a first value of an input voltage by a defined amount, resulting in an output voltage that comprises a second value, the charge pump comprises circuitry that decouples the input voltage of the charge pump from the output voltage of the charge pump and in the process mixes defined frequency disturbances back to baseband; and
an error amplifier configured to drive a micro-electromechanical system capacitive sensor, the error amplifier receives the output voltage from the charge pump and removes defined mixed down frequency disturbances, wherein an output of the error amplifier is provided as input to the micro-electromechanical system capacitive sensor.

2. The device of claim 1, wherein the circuitry comprises a first number of flying capacitors and a second number of Direct Current (DC) capacitors that are arranged in a defined configuration, wherein the defined configuration decouples the input voltage and the output voltage during distinct phases of the charge pump.

3. The device of claim 2, wherein the first number of flying capacitors comprise no fixed connection to ground, and wherein the second number of DC capacitors comprises a fixed connection to ground.

4. The device of claim 2, wherein the distinct phases comprise a first phase and a second phase, wherein the first phase is a sampling phase and the second phase is a gain phase.

5. The device of claim 2. wherein the charge pump is configured in a one to two (1:2) voltage conversion ratio,
wherein, during a first phase of the distinct phases, the first number of flying capacitors and the second number of DC capacitors are arranged in a parallel configuration connected to the input, and
wherein, during a second phase of the distinct phases, the first number of flying capacitors are configured in a parallel arrangement and the second number of DC capacitors are connected in series with the parallel arrangement towards the output.

6. The device of claim 2. wherein the charge pump is configured in a two to three (2:3) voltage conversion ratio,
wherein, during a first phase of the distinct phases, a series configuration comprising the first number of flying capacitors are placed in a parallel configuration with the second number of DC capacitors, and
wherein, during a second phase of the distinct phases, the first number of flying capacitors are configured in a parallel arrangement and the second number of DC capacitors are connected in series with the parallel arrangement.

7. The device of claim 1, wherein the charge pump is automatically configured based on the input voltage to accommodate a continuous supply range from around 1.62 volts to about 3.6 volts.

8. The device of claim 1, wherein the defined amount is equal to a value of the input voltage, and wherein a ratio of an output voltage value to an input voltage value is a function of a topology of the charge pump.

9. The device of claim 1, wherein the charge pump is configured to mix noise at a drive frequency towards direct current (DC), and wherein the error amplifier removes noise at baseband.

10. The device of claim 1, wherein the charge pump is a gearbox charge pump and the error amplifier is a sensor drive linear voltage regulator.

11. The device of claim 1, wherein the device is configured to facilitate an improvement to a signal to noise ratio as compared to a conventional signal to noise ratio.

12. A circuit comprising:
a charge pump that comprises an input terminal and an output terminal, wherein the input terminal is operatively connected to a voltage supply, and wherein the charge pump further comprises circuitry that decouples an input voltage from the voltage supply from an output voltage of the charge pump and mixes defined frequency disturbances back to baseband;
an error amplifier configured to provide high power supply rejection ratio at baseband, wherein the output terminal of the charge pump is operatively connected to an input node of the error amplifier; and
a capacitive micro-electromechanical system sensor operatively connected to an output node of the error amplifier.

13. The circuit of claim 12, wherein the circuitry of the charge pump comprises a first number of flying capacitors and a second number of Direct Current (DC) capacitors that are arranged in a defined configuration, and wherein the defined configuration decouples the input voltage and the output voltage during distinct phases of the charge pump.

14. The circuit of claim 13, wherein the charge pump is configured in a one to two (1:2) voltage conversion ratio,
wherein, during a first phase of the distinct phases, the first number of flying capacitors and the second number of DC capacitors are arranged in a parallel configuration connected to the input terminal, and
wherein, during a second phase of the distinct phases, the first number of flying capacitors are configured in a parallel arrangement and the second number of DC capacitors are connected in series with the parallel arrangement towards the output node.

15. The circuit of claim 13, wherein the charge pump is configured in a two to three (2:3) voltage conversion ratio,
wherein, during a first phase of the distinct phases, a series configuration comprising the first number of flying capacitors are placed in a parallel configuration with the second number of DC capacitors, and
wherein, during a second phase of the distinct phases, the first number of flying capacitors are configured in a parallel arrangement and the second number of DC capacitors are connected in series with the parallel arrangement.

16. The circuit of claim 13, wherein the first number of flying capacitors comprise no fixed connection to ground, and wherein the second number of DC capacitors comprises a fixed connection to ground.

17. The circuit of claim 13, wherein the charge pump is configured to accommodate a continuous supply range from around 1.62 volts to about 3.6 volts.

18. The circuit of claim 13, wherein the charge pump is configured to mix noise at a drive frequency towards a direct current (DC), and wherein the error amplifier removes supply ripple at DC.
